(19) United States
(12) Patent Application Publication
(10) Pub. No.: US 2023/0102608 A1
(43) Pub. Date: Mar. 30, 2023

(54) ENERGY HARVESTING VEHICLE

(71) Applicant: TVS MOTOR COMPANY LIMITED, Chennai (IN)

(72) Inventors: Sarkar Moumita, Chennai (IN); Kuchibhotla Sarvani, Chennai (IN); Nileshwar Pramila Rao, Chennai (IN); Dhinagar Samraj Jabez, Chennai (IN)

(73) Assignee: TVS MOTOR COMPANY LIMITED, Chennai (IN)

(21) Appl. No.: 17/796,753

(22) PCT Filed: Dec. 30, 2020
(86) PCT No.: PCT/IN2020/051065

§ 371 Date: Aug. 1, 2022

(30) Foreign Application Priority Data
Feb. 1, 2020 (IN) 202041004546

(51) Int. Cl. B62M 6/85; H01L 31/048

(52) U.S. Cl. CPC B62M 6/85; H01L 31/0481

(57) ABSTRACT

An energy harvesting vehicle includes multiple vehicle body parts and at least one solar module. Solar cells constituting at least one solar module are positioned in a section of at least one of the vehicle body parts. A pair of electrical connections of the solar cells and a protective layer of a predetermined thickness formed on a top surface of the solar cells are positioned in the section. Such a resin molded integration of a solar module to a vehicle body part allows for the installation of the solar module with non-flexible solar cells, even on non-flat surfaces or uneven surfaces.

### TECHNICAL FIELD

The invention relates to integration of solar modules to non-flat surfaces and more particularly to the rugged installation of solar modules on non-flat surfaces of a vehicle.

### BACKGROUND

A solar vehicle, that is, a vehicle running entirely or partially by on-board solar energy harvesters is an implementable solution to the energy crisis that the world is likely to face in current times as well as in future. Conventional solar panels, such as, the silicon based solar panels may be employed for automobile applications due to high efficiency, less cost, and availability of the silicon based solar panels. The silicon-based solar panels are also stable and have less light induced degradation (LID).

The solar panels on-board the vehicle, such as, a four-wheeler, an eight-wheeler, etc., are generally fixed on rooftop which is ideal for the flatness and large area availability on the vehicle. Conventional solar panels on-board a vehicle, for example, a two-wheeler are rigid, bulky, and have a large area requirement. In the case of a solar panel installed on a saddle-type two or three wheeled vehicle, the solar panel may be fixed on extra mechanical structures like a canopy over the saddle-type two or three wheeled vehicle or panels spread out around the saddle-type two or three wheeled vehicle, thereby disrupting the aerodynamics of the saddle-type two or three wheeled vehicle and adding heavily to the weight of the saddle-type two or three wheeled vehicle, but also affecting the aesthetics of the saddle-type two or three wheeled vehicle. Some advances in the solar panel technology have been able to achieve a light weight solar panel by replacing the conventional glass substrate with polymer substrate as the bottom/top layer.

Thus, the installation of the solar panels on flat surfaces of, for example, the saddle-type two or three wheeled vehicle has to be rugged and aesthetically appealing yet not affecting the aerodynamics of the vehicle.

### BRIEF DESCRIPTION OF DRAWINGS

The foregoing summary, as well as the following detailed description of the invention, is better understood when read in conjunction with the appended drawings. For the purpose of illustrating the invention, exemplary constructions of the invention are shown in the drawings. However, the invention is not limited to the specific structures and methods disclosed herein. The description of a structure referenced by a numeral in a drawing is applicable to the description of that structure shown by that same numeral in any subsequent drawing herein.

FIG. 1 exemplarily illustrates an energy harvesting vehicle with an embodiment of an installation of a solar module;

FIG. 2 exemplarily illustrates the solar module integrated to a vehicle body part of the energy harvesting vehicle;

FIGS. 3A-3B exemplarily illustrate a front view of an embodiment of a solar module integrated to a vehicle body part;

FIG. 4A exemplarily illustrates a solar cell with a positive terminal and a negative terminal;

FIG. 4B exemplarily illustrates a solar cell matrix comprising multiple electrically coupled solar cells;

FIG. 5 exemplarily illustrates a process flow schematic of integration of the solar module to the vehicle body part; and

FIG. 6 exemplarily illustrates a block diagram showing multiple solar modules as an auxiliary source of power in the energy harvesting vehicle.

### DETAILED DESCRIPTION OF THE INVENTION

Instead of installing on the separate structures extending from the body of the saddle-type two or three wheeled vehicle, the solar panels may be integrated to the body of the vehicle, such as, all body panels, visor, to harvest more incident energy. Also, in case of four wheelers, to harvest more energy, the solar panels may be integrated with the body panels of the vehicle, the doors, the bonnet, etc. However, the body panels of any type of the vehicle may have certain degree of curvature and thus are non-flat surfaces.

Non-flexibility of the solar panel is still a hindrance for using on the body of the vehicle, be it the saddle-type two or three wheeled vehicle or a multi-wheeled vehicle. The solar panel installation may still require a flat surface on the body of the vehicle for long lasting installation. The drawbacks of non-flexibility and bulkiness of the conventional crystalline silicon panels can be avoided by using some of the newer technologies like thin film copper indium gallium selenide (CIGS)/Cadmium telluride (CdTe) solar cells. However, efficiency of such thin-film solar cells is less compared to conventional silicon panels, even if the thin-film solar cells are light weight and flexible. Further, the thin film solar cells require very careful handling and are not rugged for use on rough roads, vibration loads, etc.

Existing techniques of integrating solar panels to a non-flat surface involves using a backing layer of a polymer, positioning the solar cells on it and thermo-compressing polymer layers and adhesives on the solar cells. Such integration of the solar panels to a surface is cumbersome, complex, labor intensive, and increases the weight of the part on which the solar panels are being integrated. Also, cost of tooling, manufacturing, maintenance, and replacement of the solar panels integrated to the vehicle body is comparatively higher. Associated problems of difference in thermal expansion of the polymer layers, such as, warping, bending of the solar cells, disrupts the functioning of the solar cells effectively.

In some cases, the solar panels form the vehicle body part and the vehicle body part is in turn attached to the frame of the vehicle. In such cases the warpage of the solar panels that form of the vehicle body are to be of the desired weight and shape and curvature to not affect the aerodynamics of the vehicle. By using such thermocompression techniques of the integrating the solar panels between the polymer layer layers, the weight of the body part this formed is increased. Also, high precision means for measuring and monitoring the pressure, temperature, and other parameters is required for effectively integrating the solar panels to the polymer layers and the polymer layers to a vehicle body part or to the frame of the vehicle. Also, based on the curvature on the body part, the infrastructure to integrate the solar panels has to be changed to avoiding warping of the solar panels.

Therefore, there is a long felt need for a simpler and non-cumbersome method of lightweight integration of a solar module to a surface. Further, there is a need for an energy harvesting vehicle with an integration of the solar module to non-flat external surfaces of the energy harvesting vehicle, without affecting the aerodynamics of the vehicle and one that can withstand rough loading conditions.

A method of integration of solar cells to at least one surface is disclosed. The method comprises a step of preparing the surface for positioning the solar cells. At least one solar cell matrix comprising the solar cells with a pair of electrical connections is obtained. The solar cell matrices are positioned in the prepared surface and the solar cell matrices are cured with a protective layer. The protective layer is generated on the positioned solar cell matrix in the prepared surface, for obtaining at least one solar module integrated to at least one surface.

In an embodiment, the surface may be an external surface of a vehicle body part. A vehicle whose vehicle body part has solar cells integrated on its surface is referred to as an energy harvesting vehicle. The step of preparing the surface comprises forming at least one section with a flat bottom surface in the surface using at least one manufacturing process. Further, cleaning and sanitizing the formed section to accommodate the solar cell matrix is performed. Further, a plurality of placeholders are formed in the flat bottom surface of the surface to accommodate the plurality of solar cells constituting the solar cell matrix. The method comprises the step of soldering a tab wiring on a rear surface of each of the solar cells to form a positive terminal and a negative terminal of each of the plurality of solar cells. Obtaining at least one solar cell matrix with the pair of electrical connections comprises connecting the positive terminal and a negative terminal of the solar cells in series to form the solar cell matrix. A negative terminal of a first solar cell and a positive terminal of an end solar cell of the series connected solar cells form the pair of the electrical connections of the solar module. Generating the protective layer comprises spreading a polymer resin evenly on the prepared surface with the solar cell matrix and allowing the spread liquid polymer resin to set in a predetermined time period to form the protective layer.

The energy harvesting vehicle is exemplarily disclosed herein with at least one solar module integrated to a non-flat external surface. The energy harvesting vehicle disclosed herein encompasses utilization of the vehicle body despite having a 3-dimensional structure non-flat surfaces of vehicle body for mounting the rigid solar modules.

The energy harvesting vehicle includes multiple vehicle body parts, at least one section formed in at least one of the vehicle body parts, and at least one solar module integrated to at least one of the multiple vehicle body parts. The solar module includes multiple solar cells positioned in at least one section of at least one of the vehicle body parts and a pair of electrical connections of the multiple solar cells in the section. The solar module further includes a protective layer of a predetermined thickness formed on a top surface of the solar cells in the section.

The section of at least one of the vehicle body parts is formed as a depression on an external surface of the vehicle body parts. The section includes a flat bottom surface at a predetermined depth and surrounded by multiple walls from the externals surface. The predetermined depth is equal to the predetermined thickness of the protective layer. The predetermined depth is equal to the height of the plurality of walls. the walls of the section define the extent of the solar cells and the protective layer for the solar module to be flush with the external surface of the vehicle body parts. The walls of the section extend angularly from the external surface of the vehicle body parts to the flat bottom surface. In an embodiment, the flat bottom surface of the section comprises a plurality of placeholders to accommodate the solar cells.

The pair of electrical connections of the solar cells are connected to a junction box, positioned rear of the section, electrically coupled to an energy storage device of the energy harvesting vehicle. The solar module further comprises a tab wiring on a rear surface of each of the plurality of solar cells forms a positive terminal and a negative terminal of each of the solar cells for electrically coupling the solar cells.

The solar cells are connected in series with each other using the positive terminal and the negative terminal of each of the solar cells. A negative terminal of a first solar cell of the solar cells and a positive terminal of an end solar cell of the multiple solar cells form the pair of the electrical connections of the multiple solar cells. In the case where the solar module consists of two or more solar modules, the two or more solar modules are connected in parallel to one or more charge controllers of the energy harvesting vehicle for increasing a range of the energy harvesting vehicle.

Such an installation of one or more solar modules on a non-flat external surface of the vehicle body part makes more area available for solar energy generation apart from the conventional areas used in the vehicle. This summary is provided to introduce a selection of concepts or embodiments in a simplified form that are further disclosed with an embodiment in the detailed description of the invention.

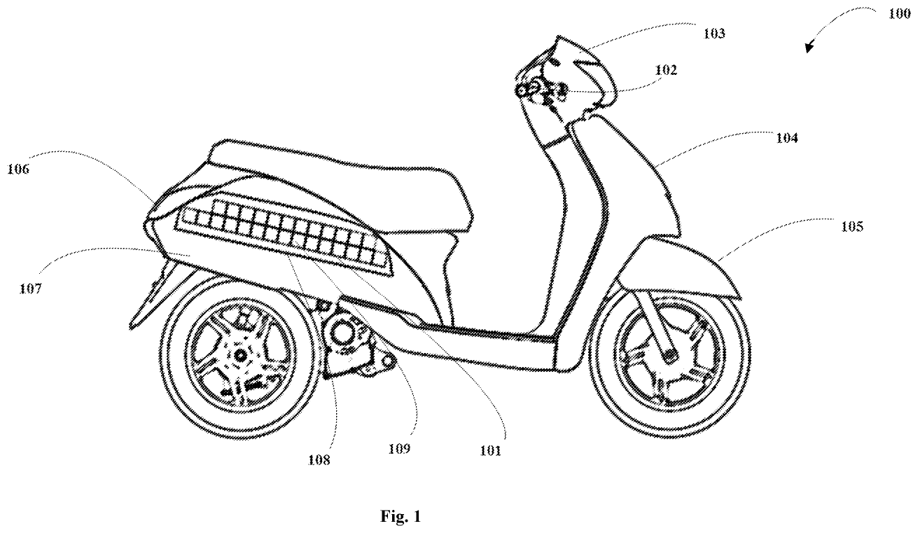

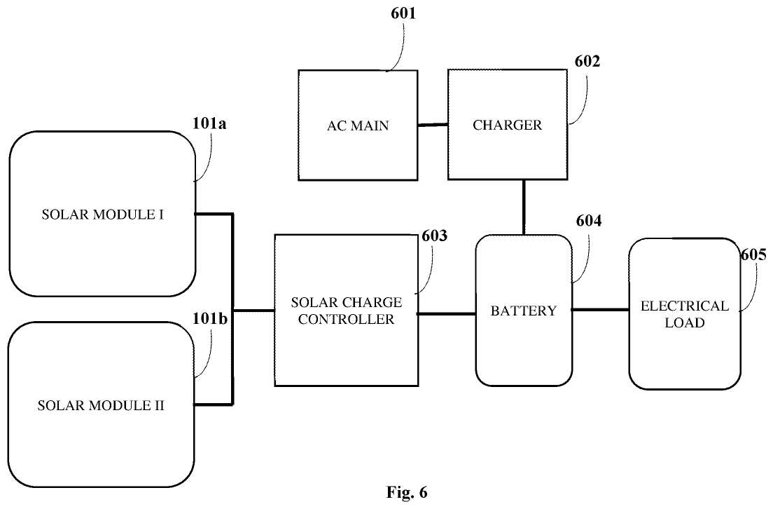

FIG. 1 exemplarily illustrates an energy harvesting vehicle 100 with an embodiment of an installation of a solar module 101. As used herein, an energy harvesting vehicle is a vehicle harvesting incident radiation, may be, solar radiation, radiation from artificial light source, etc. To harvest the incident radiation, the energy harvesting vehicle 100 comprises one or more solar modules, such as, 101. The solar module 101 comprises multiple solar cells connected in a series connection or a parallel connection to convert the incident light into electrical energy. The electrical energy generated is used to drive the energy harvesting vehicle 100, and/or to power the auxiliaries in the vehicle 100. As exemplarily illustrated, the energy harvesting vehicle 100 is a two-wheeled vehicle. In an embodiment, the energy harvesting vehicle 100 may be a three-wheeled vehicle. In another embodiment, the energy harvesting vehicle 100 may be a four-wheeled vehicle. The solar module 101 may be an auxiliary source of power in the energy harvesting vehicle 100. The energy harvesting vehicle 100 may be an electric-powered vehicle, a fuel-engine vehicle, or a hybrid electric vehicle. In an embodiment, where the energy harvesting vehicle 100 is an electric powered vehicle, the solar module 101 may charge a battery of the energy harvesting vehicle 100. A controller, for example, a solar charge controller 603 as exemplarily illustrated in FIG. 6 may select a mode of charging the battery 604 of the energy harvesting vehicle 100.

The energy harvesting vehicle 100 comprises multiple vehicle body parts, such as, vehicle body panels 104 and 107, a handle bar 102, a visor 103, a front fender 105, a fuel tank 106, etc., with non-flat surfaces and at least one solar module, such as, 101 integrated to at least one of the vehicle body parts 102, 103, 104, 105, 106, or 107, etc. The vehicle body parts 102, 103, 104, 105, 106, or 107 may be made of a metal, a fiber-reinforced plastic, a glass, or any combination thereof. The vehicle body parts 102, 103, 104, 105, 106, or 107 are three-dimensional curved parts to which the solar modules, such as, 101 are to conform. In this embodiment, the solar module 101 is integrated to a side panel 107 of the energy harvesting vehicle 100. The solar module 101 may be positioned along the body of the energy harvesting vehicle 100 in a horizontal direction or a vertical direction. The location and placement of the solar module 101 on the vehicle body part, such as, 107 is dependent on the size of the solar module 101, the direction of incident radiation, shading of the solar modules, degree of curvature of the vehicle body parts, etc. In an embodiment, one or more of solar modules, such as, 101 may be positioned on each vehicle body part, such as, 107 and may be functioning independently or in connection with each other. In an embodiment, the solar modules, such as, 101 may be a rigid or flexible in nature.

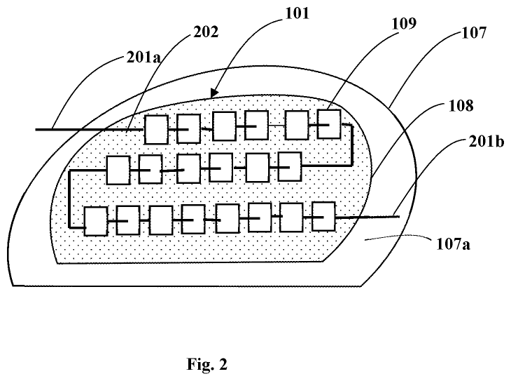

As exemplarily illustrated, the solar module 101 comprises multiple solar cells 109 that are disposed in a section 108 of the side panel 107. To integrate the solar modules, such as, 101 with the curved vehicle body parts, each of the curved vehicle body parts 102, 103, 104, 105, 106, or 107 may comprise one or more sections, such as, 108 to accommodate multiple cells 109. The solar cells 109 may be of different shapes, for example, a rectangle as exemplarily illustrated. The assembly of the solar cells 109 in the section 108 of the vehicle body part, such as, 107 confirms to the shape of the section 109, efficiently utilizing the entire planar surface of the section 109. The solar module 101 further comprises a pair of electrical connections of the solar cells 109. A protective layer of predetermined thickness of a resin is formed on a top surface of the solar cells 109 as will be disclosed in the detailed description of FIGS. 2 & 5.

FIG. 2 exemplarily illustrates the solar module 101 integrated to a vehicle body part, that is, the side panel 107 of the energy harvesting vehicle 100. As exemplarily illustrated, the solar module 101 is positioned in the section 108 of the side panel 107. The side panel 107 has a non-flat external surface 107a, that is, the side panel 107 typically has a curved surface. The section 108 of the side panel 107 has a predetermined depth and resembles a well area with multiple walls. The section 108, also has a flat bottom surface that is surrounded by the walls. The section 108 is prepared on the external surface 107a of the vehicle body part, that is, the side panel 107. The bottom surface of the section 108 is relatively flatter than the external surface of the side panel 107. The solar module 101 comprises the solar cells 109 that are small in size. The solar cells 109 are positioned in the section 108. By virtue of the smaller size of the solar cells 109, the solar cells 109 take the exact shape of the bottom surface of the section 108. The section 108 may be formed on a region of the vehicle body part, such as, 107. The section 108 is concentric with the vehicle body part 107. In an embodiment, the shape of the section 108 is similar to the shape of the vehicle body part 107. In an embodiment, the shape of the section 108 may be rectangle and be dissimilar to the shape of the vehicle body part 107.

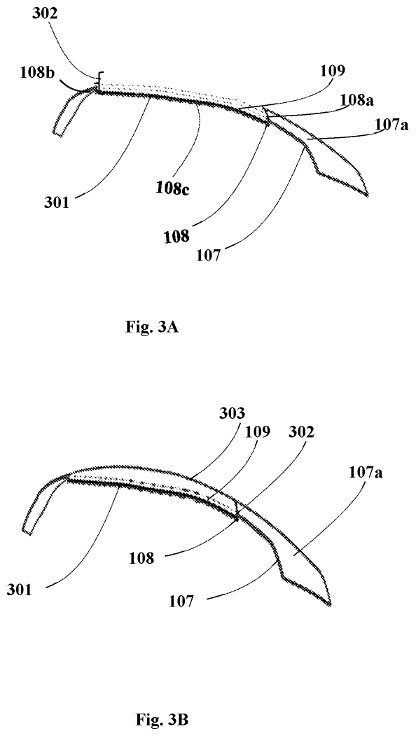

The solar module 101 further comprises a pair of electrical connections 201a and 201b of the solar cells 109 in the section 108. Each solar module 101 comprises a tab wiring 202 on a rear surface of each of the solar cells 109 that electrically couples the solar cells 109. The solar module 101, further comprises a protective layer 303 of a predetermined thickness of a resin formed on a top surface of the solar cells 109 in the section 108 of the side panel 107 as disclosed in the detailed description of FIGS. 3A-3B.

FIGS. 3A-3B exemplarily illustrate a front perspective view of the embodiment of the solar module 101 integrated to a side panel 107. The side panel 107 with the solar cells 109 positioned in the section 108 is exemplarily illustrated in FIG. 3A. The side panel 107 with the protective layer 303 formed flush with the external surface 107a of the side panel 107 is exemplarily illustrated in FIG. 3B. The solar cells 109 are positioned in the section 108 of a predetermined depth 302. The section 108 is a depression 108c on the external surface 107a of the side panel 107. The section 108 has the bottom surface 301 surrounded by the walls 108a, 108b at the predetermined depth 302 from the external surface 107a. The height of the walls 108a and 108b is equal to the predetermined depth 302. The walls 108a, 108b extend angularly from the external surface 107a to the bottom surface 301. In an embodiment, at least one of the walls 108a and 108b is perpendicular to the bottom surface 301. In an embodiment, at least one of the walls 108a or 108b is slant and forms an acute angle or an obtuse angle with the bottom surface 301. The walls 108a, 108b define the extent of positioning the solar cells 109 and the formation of the protective layer 303 to be flush with the external surface 107a. In an embodiment, the bottom surface 301 comprises multiple placeholders to accommodate the solar cells. The placeholders may be of different shapes, such as, square, rectangle, circle, hexagon, or any combination thereof. At least one solar cell 109 may be positioned in a placeholder. As exemplarily illustrated, the bottom surface 301 of the section 108 is relative flatter compared to the external surface of the side panel 107. The protective layer 303 of a liquid resin is formed on the top surface of the solar cells 109. The liquid resin is spread in the section 108 and cured to form a protective layer 303 on the solar cells 109 that is flush with the external surface 107a of the vehicle body part 107. The liquid resin fills the remaining area in the section 108 and takes the exact shape of the side panel 107 on the top surface of the solar cells 109. The thickness of the protective layer 303 is equal to the predetermined depth 302 of the section 108. The predetermined depth 302 is configured in the range of about 2 millimeters (mm) to about 5 mm. In case the depth is below 2 mm, the cured resin may fail early or get damaged due to vibration loads, and cracks may appear. In cases where the depth is more than 5 mm, a thick layer of the resin may result in poor conversion efficiency & adverse weight impact on the vehicle body part. Thus, the depth of 2 mm-5 mm is optimal for strong binding of the solar cells 108 to the vehicle body part 107 with high conversion efficiency.

The liquid resin can be chemicals, for example, epoxy, silicone elastomers, etc. The protective layer 303 is 100% transparent, UV protected, scratch resistant, impact resistant to an extent, and thermally stable. The protective layer 303 does not turn yellow on continuous exposure to sunlight, thereby the integration of the solar module 101 to the side panel 107 is aesthetically appealing in appearance even in continuous use of the energy harvesting vehicle 100. The liquid resin is cured & set at room temperature. In an embodiment, the liquid resin may be cured faster at a higher temperature.

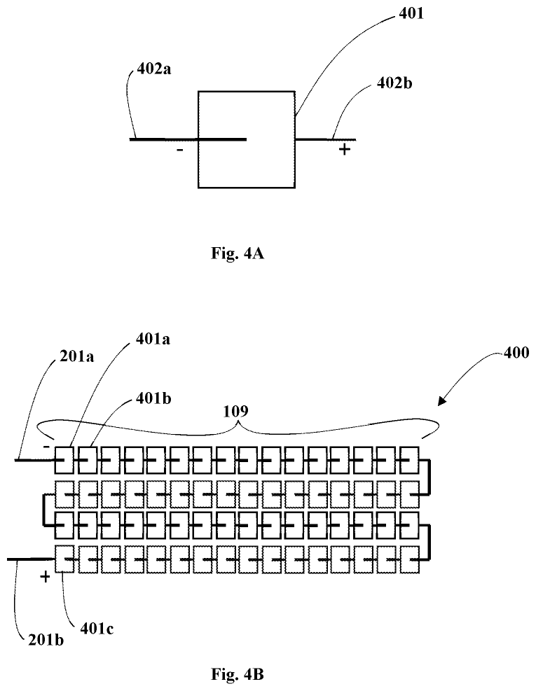

FIG. 4A exemplarily illustrates a solar cell 401 with a positive terminal 402a and a negative terminal 402b. The tab wiring 202, exemplarily illustrated in FIG. 2, on the rear surface of the solar cells 109 is used to electrically couple the solar cells 109 in the section 108. The tab wiring 202 forms a positive terminal 402b and a negative terminal 402a of each of the solar cells, such as, 401.

FIG. 4B exemplarily illustrates a solar cell matrix 400 comprising the electrically coupled solar cells 109. The solar cells, such as, 401a, 401b , . . . , 401c are connected in series with each other using the positive terminal 402b and the negative terminal 402a of each of the solar cells 109 to form the solar cell matrix 400. In an embodiment, the solar cells 109 may be connected in parallel as per the requirement of the application. The positive terminal 402b of a previous solar cell, such as, 401a is connected to the negative terminal 402a of the consecutive solar cell 401b as exemplarily illustrated. Similarly, the positive terminal 402b of the solar cell previous to the solar cell 401c is connected to the negative terminal 402a of the solar cell 401c. The negative terminal 402a of the first solar cell 401a and the positive terminal 402b of the end solar cell 401c form the pair of electrical connections 201a and 201b of the solar cells 109. The pair of electrical connections 201a and 201b of the solar cells 109 are connected to a junction box positioned in the rear of the side panel 107. The pair of electrical connections 201a and 201b are the electrical connections of the solar cell matrix 400 and in turn, of the solar module 101. The solar matrix 400 is positioned on the bottom surface 301 of the section 108 of the side panel 107 and the electrical connections 201a and 201b of the solar cells 109 extend rearwards towards the junction box at the rear of the side panel 107. The liquid resin is poured on the solar cell matrix 400 and cured to form the solar module 101 with the protective layer 303. The electrical connections 201a and 201b are thus, the electrical connections of the formed solar module 101.

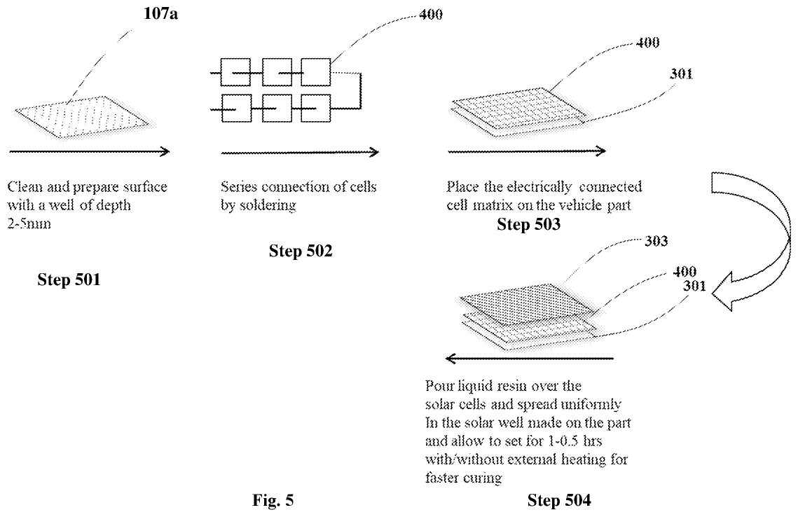

FIG. 5 exemplarily illustrates a process flow schematic of a method of integration of multiple solar cells 109 to a surface to form the solar module 101. The surface may be an external surface 107a of the vehicle body part, such as, the side panel 107. As exemplarily illustrated, the surface 107a is prepared for positioning the solar cells 109. In the energy harvesting vehicle 100 exemplarily illustrated in FIG. 1, at step 501, the external surface of the side panel 107 is prepared. That is, a section 108 with a flat bottom surface 301 is formed in the external surface 107a of the side panel 107 using a manufacturing process, such as, pressing, stamping, etc. Further, the section 108 is cleaned and sanitized to accommodate the solar cell matrix 400. In an embodiment, the placeholders in the bottom surface 301 of the section 108 of the side panel 107 are formed, cleaned, and prepared. The depth 302 of the section 108 is about 2-5 mm. In an embodiment, the bottom surface 301 can accommodate multiple solar cell matrices, such as, 400. At step 502, the solar cell matrix 400 is obtained. The solar cell matrix 400 with a pair of electrical connections 201a and 201b as exemplarily illustrated in FIG. 4 comprises solar cells 109 that are connected using the terminals 402a and 402b. A tab wiring 202 is soldered on a rear surface of each of the solar cells 109 to form a positive terminal 402b and a negative terminal 402a. Using the tab wiring, the solar cells 109 are connected to obtain a positive terminal 201a and a negative terminal 201b of the solar cell matrix 400. The positive terminal 201b and the negative terminal 201a of the solar cell matrix 400 are the electrical connections of the solar module 101. The positive terminal 201b and the negative terminal 201a of the solar cell matrix 400 is electrically connected to the junction box to connect to an energy storage device, such as a battery. Further, at step 503, the solar cell matrix 400 is positioned in the prepared surface 108. That is, the solar cell matrix 400 is positioned in the section 108 of the side panel 107. The electrical connections 201a and 201b of the solar cell matrix 400, is connected to the junction box placed either on the backside or front of the side panel 107. At step 504, a protective layer 303 is generated on the solar cell matrix 400 to obtain the solar module 101 integrated to the external surface 107a. The solar cell matrices 400 are cured in the prepared surface 108 with a protective layer 303. A liquid polymer resin is spread evenly on the solar cell matrix 400 and is allowed to set in a predetermined time period to form the protective layer 303. That is, in the energy harvesting vehicle 100, the liquid resin is poured over the solar cell matrix 400 and spread uniformly in the section 108. The liquid resin is allowed to set for 0.5 hrs-1 hr with or without external heating for faster curing. The cured resin forms the protective layer 303 of thickness equal to 2-5 mm over the solar cell matrix 400 in the section 108 of the side panel 107 and a solar module 101 integrated to the external surface 107a is obtained.

Such a resin molded integration of a solar module to a vehicle body part allows for the installation of the solar module with non-flexible solar cells, even on non-flat surfaces or uneven surfaces, such as, side panels, front panels, fuel tanks, handle bars, windshield, sunroofs, etc., of two-wheeled, there-wheeled, or four wheeled vehicles. Any small, large, flat or curved surface getting direct sunlight may be converted into an energy harvesting surface in the vehicles. Such integration also avoids extra mechanical structures, for example, a canopy for the installation of solar modules. There is significant cost reduction and weight reduction in the installation of the solar module on the vehicles by virtue of the reduced number of components in the installation. The solar module thus integrated to the vehicle body part is light weight with only two layers, namely the solar cell matrix and the protective layer. The solar module integrated to the vehicle body generates free electricity without affecting the aerodynamics of the vehicle, resulting in increase in mileage of the vehicle. The method of resin molded integration of the solar module does not require heavy machinery and specialized environment, thereby reducing infrastructure costs. Also, such a resin molded integration of the solar module avoids multiple layers of polymers, thereby not adding to the weight of the installation of the solar module while still ensuring strong binding of the solar module to the vehicle body part. It also reduces the cost associated with manufacturing such an installation of the solar module.

Also, the problems associated with the differential thermal expansion of the polymer layers surrounding the solar panel, such as, bending of the solar panel is avoided. The vehicle body part is attached to the frame of the vehicle and only the protective layer may expand in elevated temperatures. However, the expansion of the protective layer is curtailed by the walls of the section beyond which the resin cannot flow. The protective layer is flush with the external surface of the vehicle body part exhibiting seamless integration of the solar cells into the vehicle body part. The solar cells in the bottom surface remain in place until the resin is poured due to the friction offered by the bottom surface and the flatness of the bottom surface. The solar cells do not need to be fastened to the bottom surface. Also, the placeholders in the bottom surface hold individual solar cell in place until the section is cured. The resin also does not react with the terminal of the solar cells, preventing conditions such a shorting and catastrophic damage to the vehicle. In an embodiment, the junction box connected to the electrical connections may be located in the section of the vehicle body part. Members to hold the solar cell matrix in the section, such as, foam members, adhesives, struts, etc., are avoided and so are the problems associated with them during the motion of the vehicle and exposed environment of the vehicle.

The section of the vehicle body part is integral to the vehicle body part and is formed on the external surface of the vehicle body part. In an embodiment, the section in the vehicle body part may be removably attached to the vehicle body part using attachment means. Such sections may be fit into a corresponding space in the vehicle body part, one or more solar cell matrices may be placed in it, and a single protective layer may be formed to obtain a solar module. In another embodiment, the removably attachable section may be attached to the frame of the vehicle similar to the vehicle body part. Even in such assembly of the solar module, the solar module is aesthetically appealing, dust proof, and scratch resistant.

FIG. 6 exemplarily illustrates a block diagram showing the solar module 101 as an auxiliary source of power in the energy harvesting vehicle 100, such as, an electric vehicle. The battery 604 is the primary source of power in the energy harvesting vehicle 100 as disclosed in the detailed description of FIG. 1. In an embodiment, multiple solar modules, such as, 101a and 101b may be integrated with different vehicle body parts, such as, 102, 103, 104, 105, 106, or 107 of the energy harvesting vehicle 100. The solar modules, such as, 101a and 101b may be functioning either independently or connected in series or parallel to charge the battery 604. The solar modules 101a and 101b on the energy harvesting vehicle 100 when connected in parallel minimize losses due to one or more of the solar modules being in complete or partial shadow.

Each solar module, such as, 101a and 101b is an array of solar cells 109 that convert sunlight to electrical energy to charge the battery 606 of the energy harvesting vehicle 100. The solar module 101a and 101b or a main power supply 601, such as, AC mains via a charger 602 may charge the battery 604. A wiring harness of the energy harvesting vehicle 100 may connect the solar module 101a and 101b to the battery 604 at the electrical connections 201a and 201b of the solar cell matrix 400. The wiring harness may connect the solar module 101a and 101b to the battery 604 via the junction box placed in the front or the rear of the vehicle body part. A solar charge controller 603 may be a smart switch and may select between the sources of power, for example, the main power supply 601 or the solar module 101a and 101b to charge the battery 604. The solar charge controller 603 may regulate voltage and current from the solar module 101a and 101b to charge the battery 604 and avoids overcharging of the battery 604 and may protect the battery 604 from overvoltage. In an embodiment, the energy harvesting vehicle 100 may have a charge controller 603 corresponding to each solar module 101a or 101b. The battery 604 powers multiple energy consuming electrical loads 605 in the energy harvesting vehicle 100, such as, a speedometer, a horn, a turn signal lamp, etc. On employing the solar module 101a and 101b to charge the battery 604, battery life and the range of the energy harvesting vehicle 100 are enhanced. Further, the solar module 101a or 101b may act as an auxiliary source of power in IC engine vehicle.

Improvements and modifications may be incorporated herein without deviating from the scope of the invention

1.-21. (canceled)

22. A solar energy harvesting vehicle comprising:
a plurality of vehicle body parts;
at least one section formed in at least one of the plurality of vehicle body parts; and
at least one solar module integrated with the at least one of the plurality of vehicle body parts, wherein the at least one solar module comprises:
a plurality of solar cells accommodated within a plurality of placeholders, the plurality of placeholders being positioned in the at least one section formed in the at least one of the plurality of vehicle body parts,
a pair of electrical connections of the plurality of solar cells in the at least one section, and
a protective layer of a predetermined thickness formed on a top surface of the plurality of solar cells positioned in the at least one section of the at least one of the plurality of vehicle body parts to form the at least one solar module.

23. The energy harvesting vehicle as claimed in claim 22,
wherein the at least one section being formed as a depression on an external surface of the at least one of the plurality of vehicle body parts; and
wherein the at least one section comprises a flat bottom surface at a predetermined depth surrounded by a plurality of walls from the external surface of the at least one of the plurality of vehicle body parts.

24. The energy harvesting vehicle as claimed in claim 23,
wherein the predetermined depth being equal to one of the predetermined thickness of the protective layer and a height of the plurality of walls.

25. The energy harvesting vehicle as claimed in claim 23,
wherein the plurality of walls of the at least one section define an extent of the plurality of solar cells and the protective layer for the at least one solar module to be flush with the external surface of the at least one of the plurality of vehicle body parts.

26. The energy harvesting vehicle as claimed in claim 23,
wherein the plurality of walls of the at least one section extend angularly from the external surface of the at least one of the plurality of vehicle body parts to the flat bottom surface.

27. The energy harvesting vehicle as claimed in claim 23,
wherein the flat bottom surface of the at least one section comprises the plurality of placeholders to accommodate the plurality of solar cells.

28. The energy harvesting vehicle as claimed in claim 22,
wherein the pair of electrical connections of the plurality of solar cells being connected to a junction box, positioned rear of the at least one section, electrically coupled to an energy storage device of the energy harvesting vehicle.

29. The energy harvesting vehicle as claimed in claim 22,
wherein the at least one solar module comprises a tab wiring on a rear surface of each of the plurality of solar cells forms a positive terminal and a negative terminal of the each of the plurality of solar cells for electrically coupling the plurality of solar cells.

30. The energy harvesting vehicle as claimed in claim 29,
wherein the plurality of solar cells being connected in series with each other using the positive terminal and the negative terminal of the each of the plurality of solar cells, and
wherein a negative terminal of a first solar cell of the plurality of solar cells and a positive terminal of an end solar cell of the plurality of solar cells form the pair of the electrical connections of the at least one solar module.

31. The energy harvesting vehicle as claimed in claim 22,
wherein the at least one solar module consists of two or more solar modules, and
wherein the two or more solar modules being connected in parallel to one or more charge controllers of the energy harvesting vehicle for increasing a range of the energy harvesting vehicle.

32. A method for integrating a plurality of solar cells with at least one surface, the method comprising:
forming at least one section with a flat bottom surface in at least one surface of a plurality of vehicle body parts, using at least one manufacturing process;
preparing the at least one surface for positioning the plurality of solar cells, by forming a plurality of placeholders in the flat bottom surface of the at least one section;
obtaining at least one solar cell matrix comprising the plurality of solar cells with a pair of electrical connections;
accommodating the at least one solar cell matrix within at least one of the plurality of placeholders of the prepared surface; and
generating a protective layer on the positioned at least one solar cell matrix in the prepared surface, for obtaining at least one solar module integrated to the at least one surface.

33. The method as claimed in claim 32,
wherein preparing the at least one surface comprises:
cleaning and sanitizing the formed at least one section to accommodate the at least one solar cell matrix.

34. The method as claimed in claim 33,
wherein the at least one section being formed as a depression on the at least one surface with a flat bottom surface at a predetermined depth from the at least one surface and surrounded by a plurality of walls extending from the at least one surface.

35. The method as claimed in claim 34,
wherein the plurality of walls of the at least one section extend angularly from the at least one surface to the flat bottom surface.

36. The method as claimed in claim 33,
wherein the at least one surface being an external surface of at least one of a plurality of vehicle body parts.

37. The method as claimed in claim 33,
wherein the method comprises soldering a tab wiring on a rear surface of each of the plurality of solar cells to form a positive terminal and a negative terminal of the each of the plurality of solar cells.

38. The method as claimed in claim 37,
wherein obtaining the at least one solar cell matrix with the pair of electrical connections comprises:
connecting the positive terminal and the negative terminal of the each of the plurality of solar cells in series to form the at least one solar cell matrix,
wherein a negative terminal of a first solar cell and a positive terminal of an end solar cell of the series connected plurality of solar cells form the pair of the electrical connections of the at least one solar module.

39. The method as claimed in claim 33,
wherein generating the protective layer comprises:
spreading a polymer resin evenly on the prepared surface with the at least one solar cell matrix, and
allowing the spread liquid polymer resin to set in a predetermined time period to form the protective layer.

40. The method as claimed in claim 39,
wherein the prepared surface being at least one section with a flat bottom surface at a predetermined depth and surrounded by a plurality of walls,
wherein the predetermined depth being covered with the polymer resin,
wherein the predetermined depth being equal to a predetermined thickness of the protective layer, and
wherein the predetermined depth being equal to height of the plurality of walls.

41. The method as claimed in claim 40,
wherein the plurality of walls of the at least one section define an extent of positioning the plurality of solar cells and forming the protective layer for making the at least one solar module flush with the at least one surface.
